(19) United States
(12) Patent Application Publication
(10) Pub. No.: US 2014/0238605 A1
(43) Pub. Date: Aug. 28, 2014

(54) FILM THICKNESS MONITORING METHOD, FILM THICKNESS MONITORING DEVICE, AND SEMICONDUCTOR MANUFACTURING APPARATUS

(71) Applicant: Kabushiki Kaisha Toshiba, Minato-ku (JP)

(72) Inventor: Toru MIKAMI, Yokkaichi-shi (JP)

(73) Assignee: Kabushiki Kaisha Toshiba, Minato-ku (JP)

(21) Appl. No.: 14/021,221

(22) Filed: Sep. 9, 2013

Related U.S. Application Data
(60) Provisional application No. 61/768,071, filed on Feb. 22, 2013.

(51) Int. Cl. H01L 21/66; G01B 11/06

(52) U.S. Cl. CPC H01L 22/12; G01B 11/0625
USPC 156/345.13; 356/448; 156/345.25

(57) ABSTRACT

In accordance with an embodiment, a film thickness monitoring method includes applying light to a laminated body, detecting reflected light from the laminated body and outputting signals corresponding to the detected light, and judging whether a film thickness of an opaque film which is a polishing target has reached a desired film thickness. The laminated body includes a transparent film and the opaque film on the transparent film. A comparison value between the signal before polishing the opaque film and the signal after starting the polishing is obtained at predetermined time intervals, and whether the film thickness of the opaque film has reached the desired film thickness is judged based on a relationship between the comparison value of the signals and a predetermined threshold value.

### CROSS REFERENCE TO RELATED APPLICATIONS

This application is based upon and claims the benefit of U.S. provisional Application No. 61/768,071, filed on Feb. 22, 2013, the entire contents of which are incorporated herein by reference.

### FIELD

Embodiments relate to a film thickness monitoring method, a film thickness monitoring device, and a semiconductor manufacturing apparatus.

### BACKGROUND

In a manufacturing process of a semiconductor device, various kinds of materials are sequentially formed into films on a wafer, to form a laminated structure, and then the film of the uppermost layer must be polished to a desired film thickness by using chemical mechanical polishing (which will be simply referred to as “CMP” hereinafter), etching, or the like in a certain case. In such a case, it is necessary to monitor whether the film of the uppermost layer has been polished without excess or deficiency. As such monitoring of the film thickness, there has been generally adopted a technique of irradiating a laminated film with visible light, detecting reflected light from the laminated film to acquire a signal, and making reference to a previously prepared data table in which a relationship between intensity of this signal and a film thickness is written, to estimate timing for stopping a polishing process.

However, in a case that a film of the uppermost layer is an opaque film using a metal or the like as its material and a transparent film is formed as an underlayer of this opaque film, when a film thickness of the opaque film of the uppermost layer comes close to a desired value, a large amount of reflected light from the transparent film immediately below the opaque film is detected, and hence the timing for stopping the process may be erroneously estimated in a certain case.

### BRIEF DESCRIPTION OF THE DRAWINGS

In the accompanying drawings:

FIG. 1 is a view showing an outline configuration of a semiconductor manufacturing apparatus according to Embodiment 1;

FIG. 2 is a view showing an outline configuration of a film thickness monitoring device included in the semiconductor manufacturing apparatus depicted in FIG. 1 together with an inspection target;

FIG. 3A to FIG. 5 are views for explaining film thickness monitoring according to Example 1 using the film thickness monitoring device depicted in FIG. 2;

FIG. 6 and FIG. 7 are explanatory views of a film thickness monitoring method according to a reference example;

FIG. 8A to FIG. 10 are views for explaining film thickness monitoring according to Example 2 using the film thickness monitoring device depicted in FIG. 2; and

FIG. 11 is a view showing an outline configuration of a semiconductor manufacturing apparatus according to Embodiment 2.

### DETΔILED DESCRIPTION

In accordance with an embodiment, a film thickness monitoring method includes applying light to a laminated body, detecting reflected light from the laminated body and outputting signals corresponding to the detected light, and judging whether a film thickness of an opaque film which is a polishing target has reached a desired film thickness. The laminated body includes a transparent film and the opaque film on the transparent film. A comparison value between the signal before polishing the opaque film and the signal after starting the polishing is obtained at predetermined time intervals, and whether the film thickness of the opaque film has reached the desired film thickness is judged based on a relationship between the comparison value of the signals and a predetermined threshold value.

Embodiments will now be explained with reference to the accompanying drawings. Like components are provided with like reference signs throughout the drawings and repeated descriptions thereof are appropriately omitted. Furthermore, in the following description, the term “substantially” is intended to include a measurement error.

### (A) Semiconductor Manufacturing Apparatus according to Embodiment 1

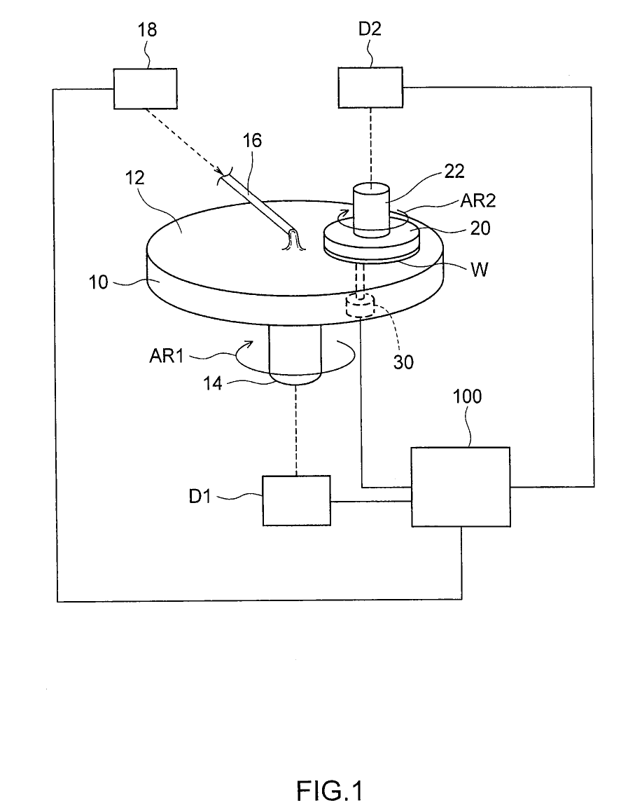

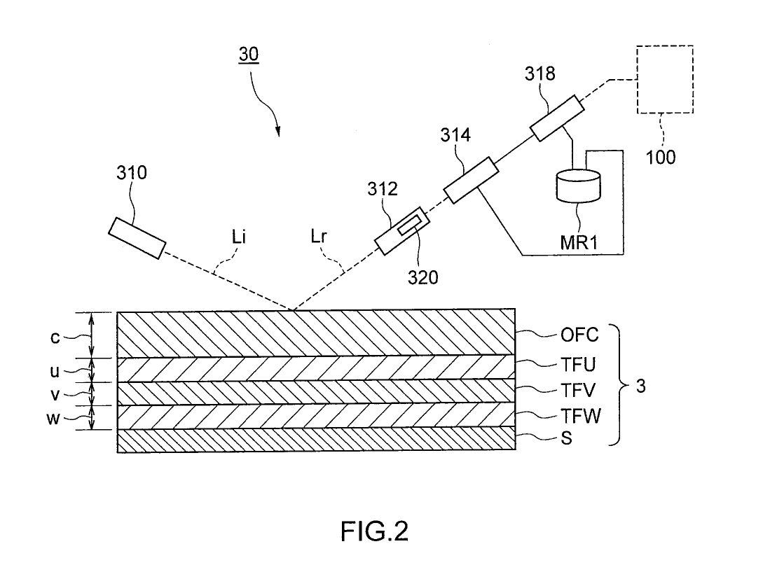

FIG. 1 is a view showing an outline configuration of a semiconductor manufacturing apparatus according to Embodiment 1. FIG. 2 is a view showing an outline configuration of a film thickness monitoring device included in the semiconductor manufacturing apparatus depicted in FIG. 1 together with an inspection target. In FIG. 2, for ease of explanation, a polishing table 10 in FIG. 1 is omitted, and the top and bottom (a vertical relationship) in FIG. 1 are reversed and shown.

The semiconductor manufacturing apparatus shown in FIG. 1 is a polishing apparatus which includes the polishing table 10, a polishing pad 12, a polishing table shaft 14, a nozzle 16, a liquid supply control mechanism 18, a top ring 20, a top ring shaft 22, a control section 100, and a film thickness monitoring device 30 and polishes a surface of a processing target based on CMP.

The polishing table 10 is coupled with the polishing table shaft 14 and supports the polishing pad 12 on an upper surface thereof. The polishing table 10 rotates in a rotating direction indicated by, e.g., a reference sign AR1 in FIG. 1 when the polishing table shaft 14 rotates by a drive mechanism D1 including a motor (not shown) and others.

The top ring 20 is coupled with the top ring shaft 22 and presses a wafer W against the polishing pad 12 while holding the wafer W in such a manner that the surface of the polishing target faces the polishing pad 12. The top ring 20 rotates in, e.g., a rotating direction AR2 when the top ring shaft 22 rotates by a drive mechanism D2 including a motor (not shown) and others.

During polishing, the polishing table 20 rotates while slurry is supplied onto the polishing pad 12 by the liquid supply control mechanism 18 through the nozzles 16, and the top ring 20 rotates while pressing the wafer W against the polishing pad 12, whereby the polishing target surface of the wafer W is polished by relative rotation of the polishing pad 12 and the wafer W. In this embodiment, the wafer W is, e.g., a silicon wafer having a laminated body 3, which has an opaque film OFC formed in the uppermost layer, formed on an upper surface thereof, and the opaque film OFC is a polishing target (see FIG. 2).

In this embodiment, the wafer W corresponds to, e.g., a substrate. It is needless to say that the substrate is not restricted to the silicon wafer and, for example, a glass substrate or a ceramic substrate is also included.

The film thickness monitoring device 30 monitors a film thickness of the polishing target during polishing, judges whether a desired film thickness has been reached, and supplies data of a judgment result to the control section 100.

The control section 100 generates respective control signals, supplies them to the respective drive mechanisms D1 and D2, the liquid supply control mechanism 18, and the film thickness monitoring device 30, controls a general polishing process, and continues or stops the polishing process based on the data of the judgment result supplied from the film thickness monitoring device 30.

As shown in FIG. 2, the film thickness monitoring device 30 includes a light-emitting section 310, a light-receiving section 312, a signal processing section 314, and a judgment section 318. Both the signal processing section 314 and the judgment section 318 are connected to a memory MR1. The memory MR1 stores a profile library which is used to identify a film thickness of a transparent film TFU immediately below the opaque film OFC as will be described later.

The light-emitting section 310 includes, e.g., a halogen light source, emits visible light Li of approximately 400 nm to approximately 800 nm, and applies this light to the laminated body 3.

In the example shown in FIG. 2, the laminated body 3 has a laminated configuration formed of the transparent films TFW, TFV, and TFU and the opaque film OFC in the mentioned order. The opaque film OFC is made of, e.g., a metal material. The transparent films TFW, TFV, and TFU and the opaque film OFC have film thicknesses of w, v, u, and c, respectively.

The incident light Li is mainly reflected on the uppermost layer, i.e., the opaque film OFC immediately after start of the polishing, and it is detected by the light-receiving section 312 as reflected light Lr. The light-receiving section 312 includes a spectroscope 320 in this embodiment, detects the reflected light Lr, measures its spectrum, and outputs a signal. It is to be noted that the light-receiving section 312 is also configured to directly output a detection signal of the reflected light Lr without using the spectroscope 320.

The signal processing section 314 processes the detection signal, creates a spectral profile or a signal intensity profile, and stores it in the memory MR1 as a measurement profile. The signal processing section 314 also uses the created measurement profile, compares detection signals before and after polishing the polishing target with each other, obtains an intensity difference as a comparison value of the signals at predetermined time intervals during the polishing process, and compares, a value of the obtained intensity difference with a predetermined threshold value. As a result of comparison, when the value of the intensity difference is substantially equal to the predetermined threshold value, this section generates a command signal for ordering to perform profile processing, and supplies this signal to the judgment section 318.

Upon receiving the command signal to perform the profile processing from the signal processing section 314, the judgment section 318 fetches from the memory MR1 a measurement profile at the moment that the value of the intensity difference is substantially equal to the predetermined value, and also fetches a theoretical profile library from the memory MR1, carries out fitting with respect to the measurement profile, and thereby identifies the film thickness u of the transparent film TFU immediately below the opaque film OFC.

The judgment section 318 also fetches a data table representing a relationship between the film thickness c of the opaque film OFC and intensity of the detection signal from the memory MR1, makes reference to the data table, and judges whether the film thickness c of the opaque film OFC has reached the desired film thickness.

When it has been determined that the film thickness c of the opaque film OFC reached the desired film thickness, the judgment section 318 generates a stop signal and supplies it to the control section 100, and the control section 100 stops the polishing process.

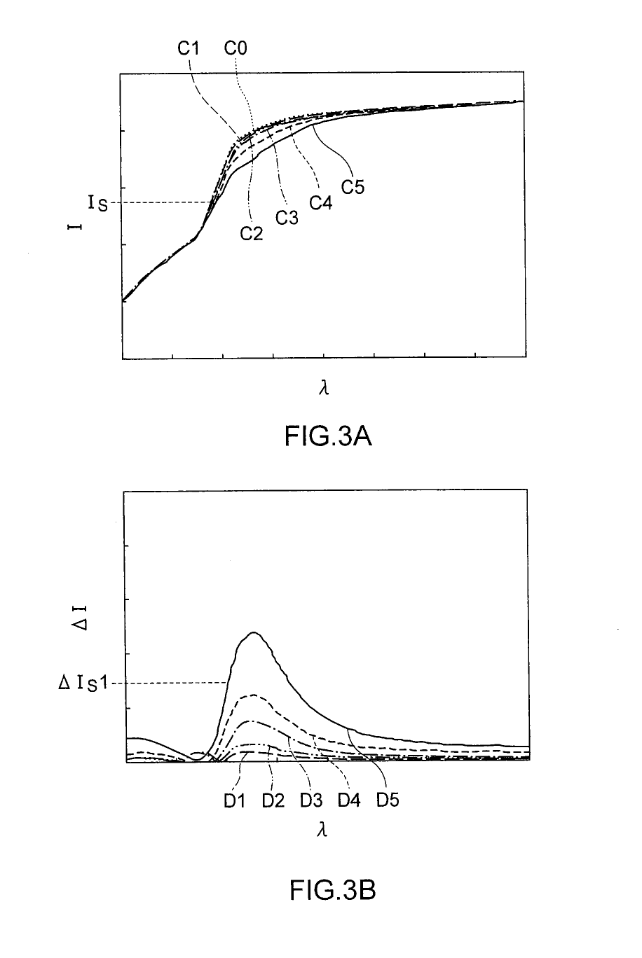

An operation of the film thickness monitoring device 30 will now be more specifically described as an embodiment of the film thickness monitoring method with reference to FIG. 3A to FIG. 5. It is to be noted that, for ease of explanation, an example where the laminated film 3 is constituted of the opaque film OFC and the transparent film TFU immediately below the opaque film OFC alone will be taken, but the present embodiment can be applied to a case where the plurality of transparent films TFU, TFV, and TFW are formed below the opaque film OFC as shown in FIG. 2 as a matter of course.

### (1) Example 1

As preprocessing, a spectral profile is acquired and its result is registered before start of the polishing process. Specifically, the incident light Li from the light-emitting section 310 is applied to the laminated film 3, the reflected light Lr is detected by the light-receiving section 312, a spectral profile is created with an abscissa representing a wavelength λ and an ordinate representing intensity I of the detected light, and this profile is stored in the memory MR1 as a measurement profile CO (see FIG. 3A).

After start of the polishing process, irradiation of the incident light Li, detection of the reflected light Lr, and creation of the spectral profile are performed at predetermined time intervals Δt, and a measurement profile Ck (k is a natural number) is stored in the memory MR1.

FIG. 3A is a view showing a specific example of the thus obtained spectral profile. FIG. 3A shows the measurement profile CO before start of the polishing and measurement profiles C1 to C5 (k=1 to 5) after start of the polishing.

Then, the signal processing section 314 obtains a difference ΔIk (k is a natural number) between the measurement profile CO and the measurement profile Ck, defines it as Dk (k is a natural number), and creates a profile chart with an abscissa representing a profile λ and an ordinate representing ΔI. In the example shown in FIG. 3A, the following relationships are achieved:

D1=CO−C1

D2=CO−C2

D3=CO−C3

D4=CO−C4

D5=CO−C5

FIG. 3B shows a profile chart of D1 to D5.

Subsequently, the signal processing section 314 in FIG. 2 judges whether ΔIk of the profile Dk exceeds a prepared threshold value ΔIs1.

If the following relationship is achieved and ΔIk does not exceed ΔIs1, the control section 100 in FIG. 1 continues the polishing process as it is:

ΔIk<ΔIs1

This comparison/judgment process is continued until ΔIk≈ΔIs1 is attained.

As a result of continuing the polishing process, when the following relationship is achieved and ΔIk is substantially equal to ΔIs1, the signal processing section 314 generates a command signal for ordering to perform profile processing and supplies it to the judgment section:

ΔIk≈ΔIs1

In the example shown in FIG. 3B, ΔI exceeds ΔIs1 when k=5 is attained, i.e., at the stage of D5.

The judgment section 318 that has received the command signal from the signal processing section 314 performs fitting between the measurement profile Ck at the moment that ΔIk≈ΔIs1 was achieved and a library of theoretical profiles TF1 (Ci, Uj) (j is a natural number) having the film thickness of the opaque film OFC of the uppermost layer in FIG. 2 and the film thickness of the underlying transparent film TFU film as parameters, and thereby identifies the film thickness u of the underlying transparent film TFU. In this embodiment, the library of the theoretical profiles TF1 (Ci, Uj) (j is a natural number) corresponds to, e.g., a first library.

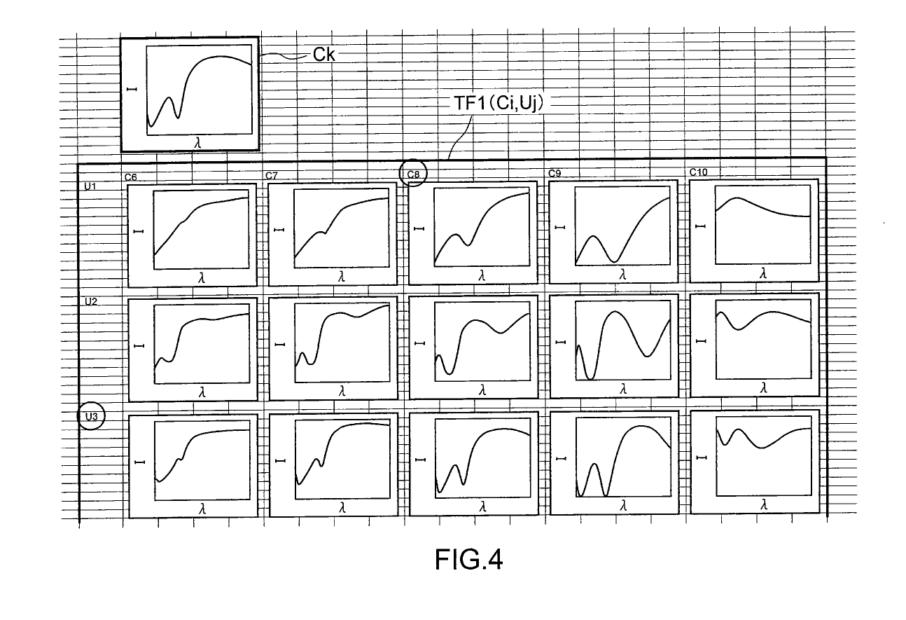

FIG. 4 shows an example of the measurement profile Ck and a specific example of part of the library of the theoretical profiles TF1 (Ci, Uj). In the example shown in FIG. 4, it is determined that a shape of TF1 (C8, U3) (i=8, j=3) in the library of the theoretical profiles TF1 (Ci, Uj) is the closest to a shape of the measurement profile Ck, the film thickness u of the transparent film TFU in FIG. 2 is identified as U3, and the film thickness c of the opaque film OFC is identified as C8.

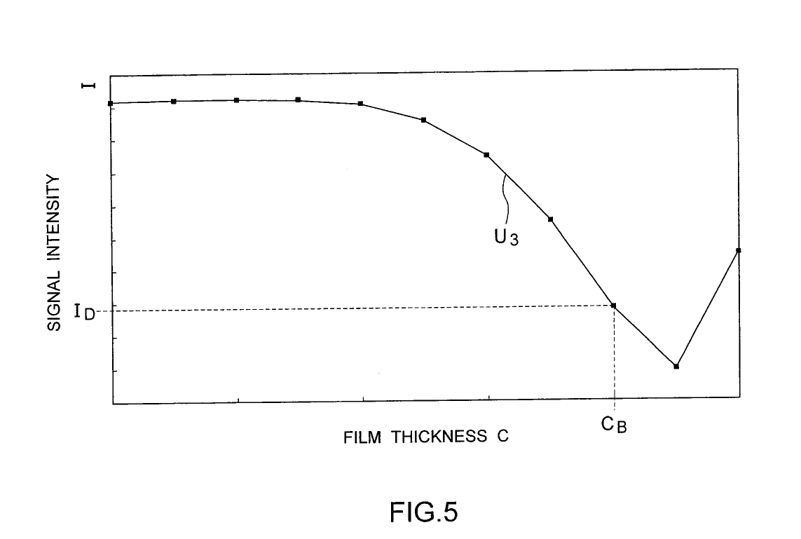

When the film thickness of the underlying transparent film TFU in FIG. 2 is identified in this manner, checking a relationship between the film thickness c of the opaque film OFC associated with the identified film thickness of the transparent film TFU and the signal intensity I enables judging whether the subsequent polishing process should be continued. FIG. 5 is a graph showing an example of the relationship between the film thickness c of the opaque film OFC and the signal intensity I when the film thickness u of the transparent film TFU in FIG. 2 has been identified as U3.

In the relationship shown in FIG. 5, signal intensity associated with a desired film thickness C_{B} is I_{D}, and the judgment section 318 in FIG. 2 compares this signal intensity I_{D} with a measurement value I of the signal intensity (a profile U₃ in FIG. 5) during the polishing process, generates a stop signal when these values have become very close to each other, and supplies it to the control section 100 in FIG. 1. Upon receiving the stop signal from the judgment section 318 in FIG. 2, the control section 100 stops the polishing process.

According to this example, since the spectral profile is used as the measurement profile, a film thickness of the opaque film of the polishing target can be highly accurately identified. It is to be noted that, as shown in FIG. 2, for a case that not only the transparent film TFU immediately below the opaque film but also the transparent films TFV and TFW of the two layers are formed below the opaque film OFC, the library with parameters whose number is increased according to the transparent films TFV and TFW of the two layers is used.

### (2) Reference Example

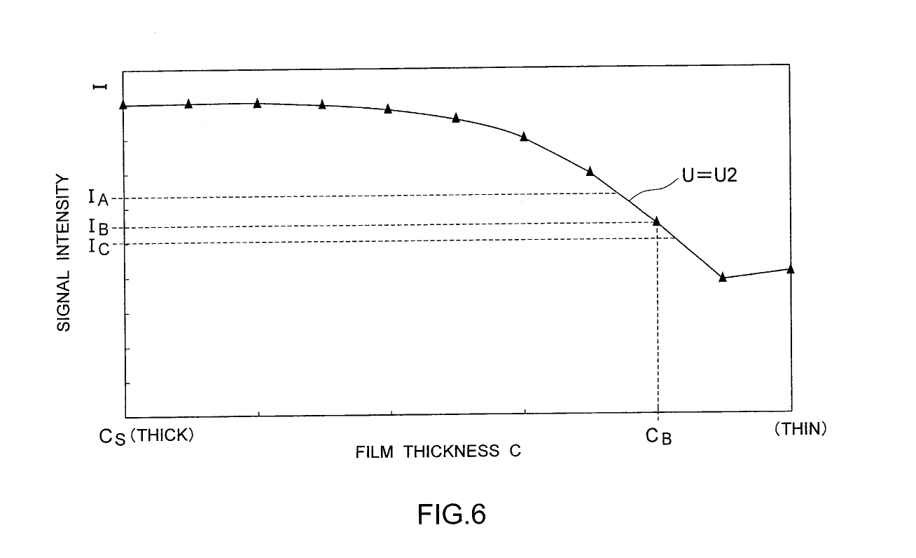

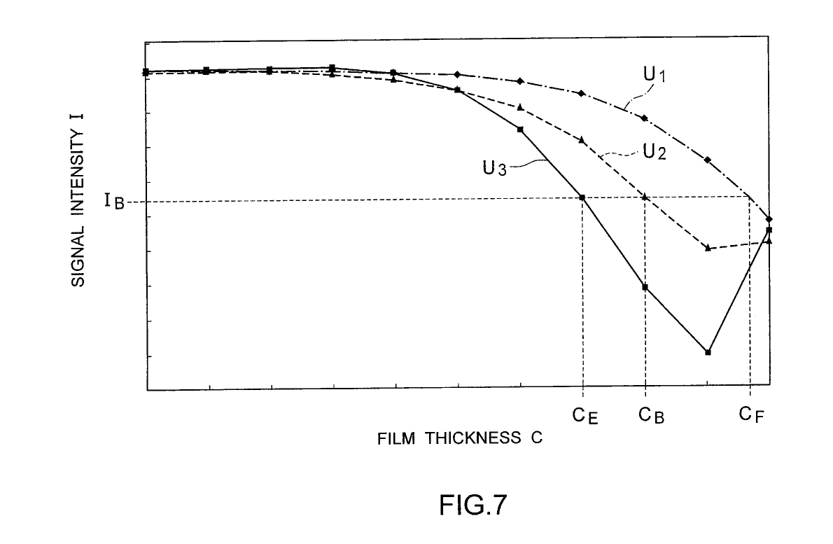

A reference example concerning Example 1 will now be described with reference to FIG. 6 and FIG. 7.

A film thickness monitoring method according to this reference example is the same as Embodiment 1 in that the incident light Li is applied to the laminated layer 3 during the polishing process, the reflected light Lr is detected, and the spectral profile having an abscissa representing the profile λ, and an ordinate representing the intensity I of the detected light is created, as shown in FIG. 2.

In this reference example, an arbitrary wavelength in the obtained spectral profile is selected, and the light intensity I of the selected wavelength is evaluated. In regard to the signal intensity I, as shown in FIG. 6, a relationship of the opaque film OFC and the film thickness c has been obtained in advance. It is to be noted that, in FIG. 6, a reference sign C_{B} represents a desired film thickness of the opaque film OFC and a reference sign C_{S} represents a film thickness of the opaque film OFC before the polishing process.

In this reference example, the light intensity I measured during the polishing process is compared with signal intensity I_{B} associated with the desired film thickness C_{B}. When a value of the measured light intensity I is larger than a value of the desired light intensity I_{B} (e.g., when I=I_{A} in FIG. 6), it is determined that the film thickness c of the opaque film OFC in FIG. 2 has not reached the desired film thickness C_{B}, and the polishing process is continued. On the other hand, when the value of the measured light intensity I is smaller than the value of the desired light intensity I_{B} (e.g., when I=I_{C} in FIG. 6), it is determined that the film thickness c of the opaque film OFC in FIG. 2 has reached the desired film thickness, and the polishing process is terminated.

As described above, in this reference example, whether the process of polishing the opaque film OFC should be continued or stopped is determined based on whether the value of the intensity I of the detected light in the polishing process has reached the value of the light intensity I_{B} corresponding to the desired value C_{B}.

Since the light intensity I is fixed irrespective of the film thicknesses w, v, and u of the underlying transparent films TFW, TFV, and TFU in a thick state (C=C_{S}) before polishing the opaque film OFC, the film thicknesses w, v, and u of these transparent films TFW, TFV, and TFU cannot be recognized by the monitoring method according to this reference example. Therefore, in a case of starting and continuing the polishing process, there is no other way but to consider the film thicknesses w, v, and u of the transparent films TFW, TFV, and TFU as being equal to their design values and advance the processing.

However, when the polishing process advances and the opaque film OFC becomes thinner so that the film thickness of the opaque film OFC is close to the desired film thickness C_{B}, the incident light Li starts to transmit the opaque film OFC. Therefore, characteristics of the light intensity I and the film thickness c of the opaque film OFC vary in accordance with the film thickness u of the transparent film TFU immediately below the opaque film OFC.

For example, as shown in FIG. 7, in a case that the light intensity T_{B} is unchanged but the film thickness u of the underling transparent film TFU is U₃, the film thickness of the opaque film OFC is identified as C_{E}, and if the polishing process is stopped at this point the relationship between the identified film thickness C_{E} of the opaque film OFC and the desired film thickness C_{B} becomes C_{E}>C_{B}, and hence the desired film thickness C_{B} is not reached yet. Therefore, the polishing process must be again performed after temporary stopping this process, thus resulting in an increase in manufacturing cost and a reduction in throughput by the amount corresponding to the repolishing.

On the other hand, if the film thickness U of the underlying transparent film TFU is U₁, the film thickness c of the opaque film OFC is identified as C_{F}, the relationship between the identified film thickness C_{F} of the opaque film OFC and the desired film thickness C_{B} becomes C_{B}>C_{F}, and the film thickness C_{F} has become thinner than the desired film thickness C_{B}, i.e., the polishing has been excessively performed. As a result, a yield ratio may be possibly deteriorated.

In contrast to the above-described reference example, according to the above-mentioned Example 1, a difference between signal profiles before and after the polishing process is obtained, when this difference has substantially reached a threshold value it is determined that the opaque film has become sufficiently transparent, and a film thickness of the underlying transparent film is identified, and the film thickness of the opaque film is measured based on the relationship between the signal intensity associated with the identified film thickness of the underlying transparent film and the film thickness of the opaque film in the subsequent process. Therefore, the film thickness of the opaque film as the polishing target can be accurately measured. Further, continuation/stop of the polishing process can be accurately determined based on a correct measurement value. Accordingly the opaque film of the uppermost layer can be machined up to a desired thickness.

### (3) Example 2

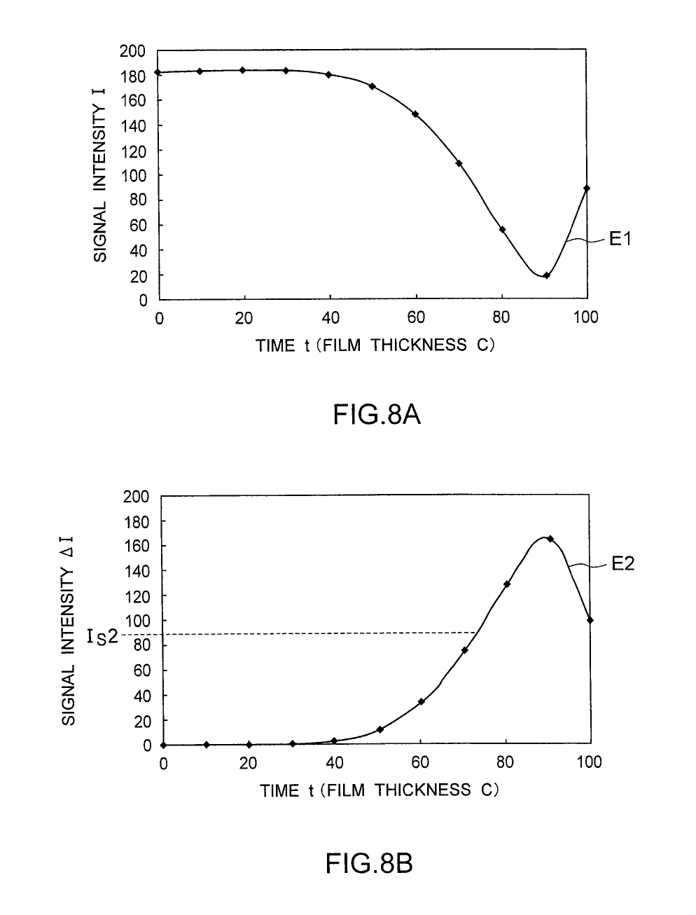

The film thickness monitoring method according to Example 2 will now described with reference to FIG. 8A to FIG. 10. This example is suitable for accurately identifying a film thickness of an opaque film without using a spectroscope.

This example is also the same as Embodiment 1 in that incident light Li is applied to a laminated film 3 and reflected light Lr is detected, as shown in FIG. 2. In this example, in place of creating a spectral profile, a time transition of measurement profile intensity after start of polishing is observed with a time point immediately before start of the polishing being determined as a reference.

Specifically, the time point immediately before start of the polishing is determined as a time t=0, light intensity I of a measurement profile obtained at this moment is measured, and this intensity is stored in a memory MR1.

Then, the polishing relative to an opaque film OFC is started, and the light intensity I at each of times t=t1, t2, t3 . . . is measured and stored in the memory MR1.

FIG. 8A is a graph obtained by plotting each light intensity I at each of the times t=t1, t2, t3 . . . and providing a profile E1.

Subsequently, like Example 1, a difference ΔI between the light intensities I before and after start of the polishing is obtained. FIG. 8B is a graph showing a profile E2 of ΔI obtained in this manner.

Then, a signal processing section 314 in FIG. 2 judges whether ΔI exceeds a prepared threshold value ΔIs2.

If the following relationship is achieved and ΔI does not exceed ΔIs, a control section 100 in the polishing apparatus shown in FIG. 1 continues the polishing process as it is:

ΔI<ΔIs2

This comparison/judgment process is continued until ΔI≈ΔIs2 is attained.

As a result of continuing the polishing process, when the following relationship is achieved and ΔI is substantially equal to ΔIs2, the signal processing section 314 in FIG. 2 generates a command signal for ordering to perform profile processing and supplies it to a judgment section 318:

ΔI≈ΔIs2

The judgment section 318 that has received the command signal from the signal processing section 314 performs fitting between a measurement profile WF2 at a time point that ΔI≈ΔIs2 was achieved and a library of theoretical profiles TF (t, Uj) (j is a natural number) and thereby identifies the film thickness u of the underlying transparent film TFU. The library is prepared with the use of a time t from start of the polishing (associated with a film thickness c of the opaque film OFC) and a film thickness u of an underlying transparent film TFU as parameters and stored in the memory MR1. In this example, the library of the theoretical profiles TF2 (t, Uj) (j is a natural number) corresponds to, e.g., a second library.

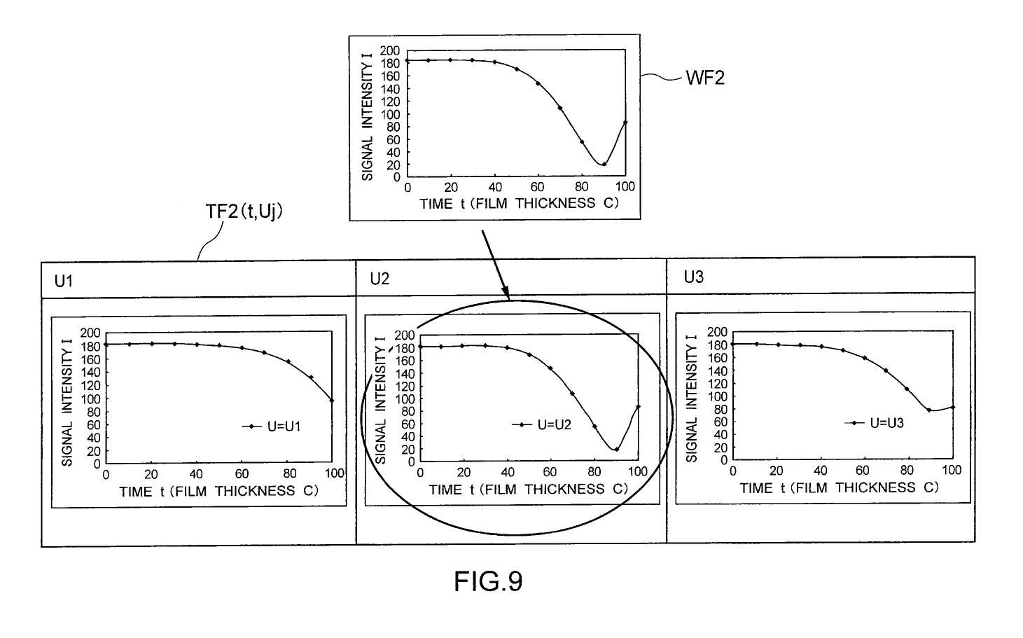

FIG. 9 shows an example of the measurement profile WF2 and a specific example of part of the library of the theoretical profiles TF2 (t, Uj). In the example shown in FIG. 9, it can be determined that a shape of TF2 (t, U2) (j=2) in the library of the theoretical profiles TF2 (u, Uj) is the closest to a shape of the measurement profile WF2, and hence the film thickness u of the transparent film TFU is identified as U2.

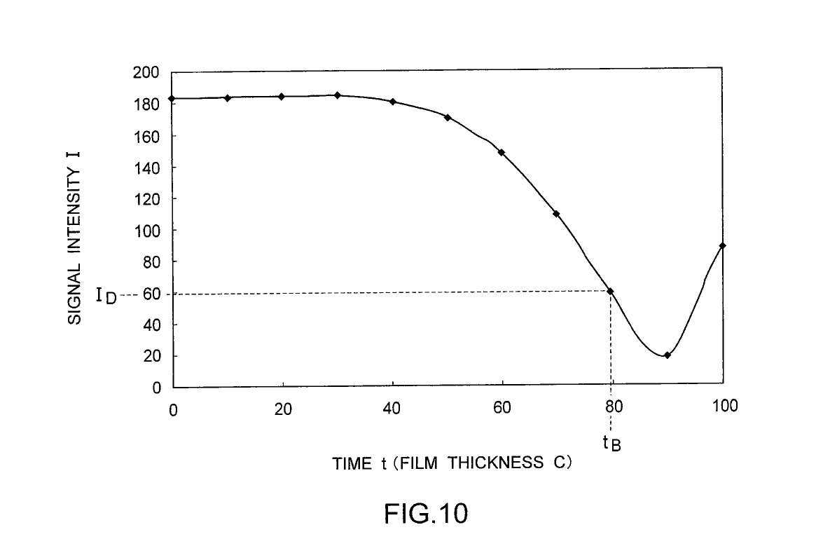

When the film thickness u of the underlying transparent film TFU is identified in this manner, checking a relationship between the time t from start of the polishing associated with the identified film thickness u of the transparent film TFU (associated with the film thickness c of the opaque film OFC) and the signal intensity I enables judging whether the subsequent polishing process should be continued. FIG. 10 is a graph showing an example of the relationship between the time t from start of the polishing and the signal intensity I when the film thickness u of the transparent film TFU is identified as U2.

In the relationship shown in FIG. 10, signal intensity for a time t_{B} that elapses after start of the polishing and is associated with the desired film thickness c of the opaque film OFC is I_{D}, and the judgment section 318 in FIG. 2 compares this signal intensity I_{D} with a measurement value I of the signal intensity during the polishing, generates a stop signal when these values are sufficiently close to each other, and supplies this signal to the control section 100 in the polishing apparatus shown in FIG. 1. When the control section 100 receives the stop signal from the judgment section 318 in FIG. 2, it stops the polishing process.

According to this embodiment, the film thickness of the transparent film immediately below the opaque film can be accurately identified without using a spectral profile, and whether the polishing process for the opaque film should be continued can be accurately judged.

According to the film thickness monitoring method based on at least one of the foregoing embodiments, the film thickness of the opaque film can be highly accurately identified.

Further, according to the film thickness monitoring device based on at least one of the foregoing embodiments, whether the polishing process for the opaque film should be continued can be accurately judged.

### (B) Semiconductor Manufacturing Apparatus according to Embodiment 2

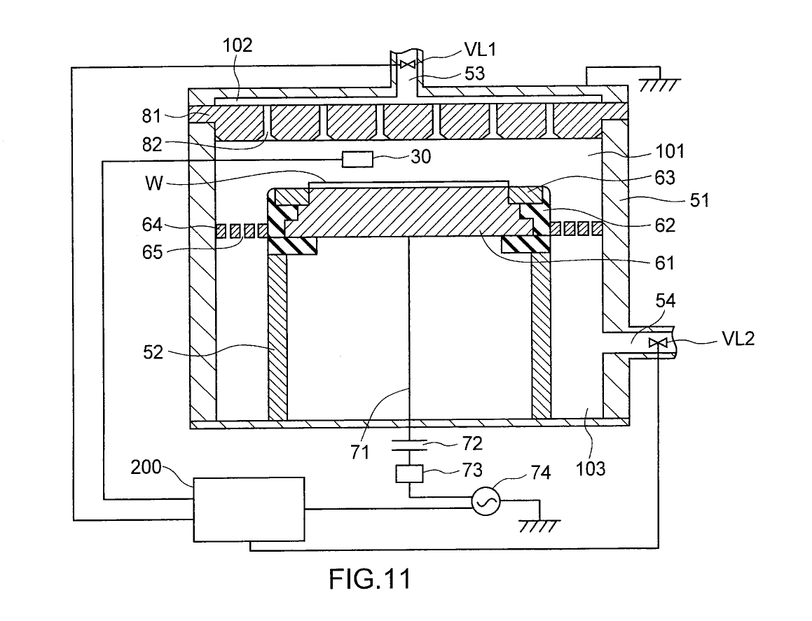

FIG. 11 is a view showing an outline configuration of a semiconductor manufacturing apparatus according to Embodiment 2. The semiconductor manufacturing apparatus shown in FIG. 11 is a reactive ion etching (which will be simply referred to as “RIE” hereinafter) apparatus which includes a chamber 51 into which a process gas is introduced, a stage 61, a high-frequency power supply 74, a shower head 81, control section 200, and a film thickness monitoring device 30, converts the process gas into plasma between the shower head 81 and the stage 61 by using high-frequency power, and etches a processing target by using ions in a plasma gas. It is to be noted that in the following explanation terms “upper” and “lower” correspond to an upstream side and a downstream side of the process gas flowing through the chamber 51, respectively.

The stage 61 is provided in the chamber 51, horizontally supports a processing target, e.g., a wafer W having a laminated body 3 shown in FIG. 2 formed thereon, and functions as a lower electrode. On a surface of the stage 61 is provided a holding mechanism (not shown) such as an electrostatic chuck mechanism that electrostatically adsorbs the wafer W. An insulating ring 62 is provided to the stage 61 so as to cover a side surface and a peripheral edge portion of a bottom surface of the stage 61, and a focus ring 63 is provided on an upper outer periphery of the stage 61 that is covered with the insulating ring 62. This focus ring 63 is a member provided to adjust an electric field in such a manner that the electric field is not deflected to a vertical direction (a direction vertical to a wafer surface) at the peripheral edge portion of the wafer W at the time of etching the wafer W.

In this embodiment, the stage 61 is supported on a support section 52, which cylindrically protrudes upward in the vertical direction from a bottom wall near the center of the chamber 51, via the insulating ring 62 so that the stage 61 can be placed near the center in the chamber 51. A baffle plate 64 is provided between the insulating ring 62 and the sidewall of the chamber 51. A plurality of gas discharge holes 65 which are pierced in a plate thickness direction are provided in the baffle plate 64.

Furthermore, a feeder line 71 through which the high-frequency power is supplied is connected to the stage 61, and the high-frequency power supply 74 is connected to this feeder line 71 through a blocking capacitor 72 and a matching box 73. The high-frequency power having a predetermined frequency is supplied from the high-frequency power supply 74 to the stage 61. The high-frequency power supply 74 is connected to the control section 200 and receives a control signal, and an application voltage and others for the stage 61 are thereby controlled.

The shower head 81 that functions as an upper electrode is provided above the stage 61 so that the shower head 81 can face the stage 61 which functions as the lower electrode. The shower head 81 is fixed on a sidewall near the upper portion of the chamber 51, which is apart from the stage 61 by a predetermined distance, so as to face the stage 61 in parallel. By such a configuration, the shower head 81 and the stage 61 constitute a pair of parallel plate electrodes. Moreover, a plurality of gas supply paths 82 which are pierced in the plate thickness direction are provided in the shower head 81.

In this embodiment, the shower head 81, the stage 61, the feeder line 71, the blocking capacitor 72, the matching box 73, and the high-frequency power supply 74 correspond to, e.g., a plasma generation unit.

A gas supply port 53 through which the process gas that is used at the time of a plasma treatment is supplied is provided near the upper portion of the chamber 51, and a non-illustrated gas supply apparatus is connected to the gas supply port 53 through a pipe. A valve VL1 is provided in the gas supply port 53, connected to the control section 200, receives a control signal, and subjected to opening/closing and aperture adjustment, whereby an introduction amount of the process gas is controlled.

A gas discharge port 54 is provided in a chamber 11 below the stage 61 and the baffle plate 64, and a non-illustrated vacuum pump is connected to the gas discharge port 54 through a pipe. A valve VL2 is provided in the gas discharge port 54, connected to the control section 200, receives a control signal, and subjected to opening/closing and aperture adjustment, whereby a discharge amount of the process gas is controlled.

A region partitioned by the stage 61, the baffle plate 64, and the shower head 81 in the chamber 51 serves as a plasma treatment chamber 101, an upper region in the chamber 51 partitioned by the shower head 81 serves as a gas supply chamber 102, and a lower region in the chamber 51 partitioned by the stage 61 and the baffle plate 64 serves as a gas discharge chamber 103.

The film thickness monitoring device 30 is installed on the stage 61 in the plasma treatment chamber 101, monitors a film thickness of a processing target, e.g., the opaque film OFC shown in FIG. 2 during the etching processing, judges whether a desired film thickness has been obtained, and supplies data of a judgment result to the control section 100.

The control section 100 generates respective control signals, supplies them to the high-frequency power supply 74, the valves VL1 and VL2, and the film thickness monitor device 30, controls a general etching process, and continues or stops the etching process based on the data of the judgment result supplied from the film thickness monitoring device 30.

An outline of the etching process implemented by the RIE apparatus according to this embodiment will now be described. First, a wafer W which is a processing target is mounted on the stage 61, and it is fixed by, e.g., the electrostatic chuck mechanism. Then, the inside of the chamber 51 is vacuumed by a non-illustrated vacuum pump connected to the gas discharge port 54. At this time, the gas discharge chamber 103 is connected to the plasma treatment chamber 101 through the gas discharge holes 65 provided in the baffle plate 64, the plasma treatment chamber 101 is connected to the gas supply chamber 102 through the gas supply paths 82 in the shower head 81, and hence the vacuum pump connected to the gas discharge port 54 performs vacuum drawing in the entire chamber 51.

Then, when the inside the chamber 51 reaches a predetermined pressure, the valve VL1 is opened in response to a control signal from the control section 200, and the process gas is supplied from a non-illustrated gas supply apparatus into the gas supply chamber 102 and further supplied into the plasma treatment chamber 101 through the gas supply paths 82 in the shower head 81.

When the inside of the plasma treatment chamber 101 reaches a predetermined pressure, in a state that the shower head 81 (the upper electrode) is grounded, the high-frequency power supply 74 applies a high-frequency voltage to the stage 61 (the lower electrode) in accordance with a control signal supplied from the control section 200, whereby plasma is generated in the plasma treatment chamber 101. Here, since the high-frequency voltage is applied to the lower electrode, a potential gradient is produced between the plasma and the wafer, ions in the plasma gas moving toward the stage 61 are accelerated, and the etching processing is carried out.

A film thickness of the processing target is monitored by the film thickness monitoring device 30, and a monitoring result is supplied to the control section 200. When the film thickness monitoring device 30 determines that the film thickness of the processing target has not reached a desired film thickness, the control section 200 continues the etching processing. When the film thickness monitoring device 30 determines that the film thickness of the processing target has reached the desired film thickness, the control section 200 allows the high-frequency power supply 74 to stop application of the high-frequency voltage in accordance with data of a judgment result supplied from the film thickness monitoring device 30, closes the valve VL1, stops introduction of the processing gas. As a result, the etching processing is stopped.

Since a configuration and an operation of the film thickness monitoring device 30 provided in the RIE apparatus according to this embodiment and the film thickness monitoring method are substantially equal to the contents described in regard to the film thickness monitoring device provided in the polishing apparatus according to Embodiment 1, a detailed description thereof will be omitted. However, in a case of RIE, as different from CMP for polishing a surface so as to be substantially flash in each polishing operation, since slight irregularities are produced on a surface of a processing target, a drive mechanism (not shown) is provided to the film thickness monitoring device 30, and it is desirable to scan the surface of the processing target during each monitoring time by horizontally moving this device and compare each average value with each threshold value.

According to at least one of the semiconductor manufacturing apparatuses described above, since the film thickness monitoring device is provided, the manufacturing process can be carried out without excess or deficiency, and a yield ratio and throughput in manufacture of a semiconductor device can be improved. According to the semiconductor manufacturing apparatus based on at least one of the foregoing embodiments, whether the process of polishing the opaque film should be continued or stopped can be accurately judged, and hence the opaque film can be polished without excess or deficiency.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film thickness monitoring method for an opaque film, comprising:
applying light to a laminated body comprising a transparent film and an opaque film which is a polishing target on the transparent film;
detecting reflected light from the laminated body and outputting signals corresponding to the detected light; and
obtaining a comparison value between the signal before polishing the opaque film and the signal after starting the polishing at predetermined time intervals, and judging whether a film thickness of the opaque film has reached a desired film thickness based on a relationship between the comparison value of the signals and a predetermined threshold value.

2. The method of claim 1,
wherein whether the film thickness of the opaque film has reached the desired film thickness can be judged based on whether an intensity comparison value of the signals has substantially reached the predetermined threshold value.

3. The method of claim 2, further comprising:
performing fitting between a measurement profile at a time point that the intensity comparison value of the signals has substantially reached the predetermined threshold value and a prepared first library of theoretical profiles of the transparent film and the opaque film, and identifying a film thickness of the transparent film; and
identifying the film thickness of the opaque film based on the identified film thickness of the transparent film.

4. The method of claim 3,
wherein the film thickness of the opaque film is identified by making reference to a relationship between signal intensity associated with the identified film thickness of the transparent film and the opaque film.

5. The method of claim 3,
wherein the intensity comparison value of the signals is obtained from a spectral profile, and
both the measurement profile and the theoretical profile are spectral profiles.

6. The method of claim 2, further comprising performing fitting between signal intensity at a time point that the intensity comparison value of the signals has substantially reached the predetermined threshold value and a prepared second library of theoretical profiles of the transparent film, and identifying a film thickness of the transparent film.

7. The method of claim 6,
wherein whether the film thickness of the opaque film has reached the desired film thickness is judged by making reference to a relationship between signal intensity associated with the identified film thickness of the transparent film and a polishing time.

8. The method of claim 1,
wherein the transparent film is constituted of a plurality of layers.

9. A film thickness monitoring device for an opaque film, comprising:
a light-emitting section which applies light to a laminated body comprising a transparent film and an opaque film on the transparent film;
a detecting section which detects reflected light from the laminated body and outputs signals; and
a judgment section which obtains a comparison value of the signal before polishing the opaque film and the signal after starting the polishing at predetermined time intervals and judges whether the opaque film has reached a desired film thickness based on a relationship between an intensity comparison value of the signals and a predetermined threshold value.

10. The device of claim 9,
wherein the judgment section judges whether the film thickness of the opaque film has reached the desired film thickness based on whether the intensity comparison value of the signals has substantially reached the predetermined threshold value.

11. The device of claim 10, further comprising a recording device which stores a prepared first library of theoretical profiles of the transparent film and the opaque film,
wherein the judgment section performs fitting between a measurement profile at a time point that the intensity comparison value of the signals has substantially reached the predetermined threshold value and the first library, thereby identifies a film thickness of the transparent film, and identifies the film thickness of the opaque film based on the identified film thickness of the transparent film.

12. The device of claim 11,
wherein the judgment section makes reference to a relationship between signal intensity associated with the identified film thickness of the transparent film and the opaque film, and thereby identifies the film thickness of the opaque film.

13. The device of claim 11, further comprising a spectroscope,
wherein both the measurement profile and the theoretical profile are spectral profiles.

14. The device of claim 11,
wherein the recording device further stores a prepared second library of theoretical profiles of the transparent film, and
the judgment section performs fitting between signal intensity at a time point that the intensity comparison value of the signals has substantially reached the predetermined threshold value and the second library, and thereby identifies the film thickness of the transparent film.

15. The device of claim 14,
wherein the judgment section makes reference to a relationship between signal intensity associated with the identified film thickness of the transparent film and a polishing time and thereby judges whether the film thickness of the opaque film has reached the desired film thickness.

16. A semiconductor manufacturing apparatus comprising:
a mechanism which polishes an opaque film of a laminated body comprising a transparent film and the opaque film on the transparent film; and
a film thickness monitoring device which monitors a film thickness of the opaque film,
wherein the film thickness monitoring device comprises:
a light-emitting section which emits light and applies it to the laminated body;
a detecting section which detects reflected light from the laminated body and outputs signals; and
a judgment section which obtains a comparison value of the signal before polishing the opaque film and the signal after starting the polishing at predetermined time intervals, and judges whether the opaque film has reached a desired film thickness based on a relationship between intensity comparison value of the signals and a predetermined threshold value.

17. The apparatus of claim 16,
wherein the polishing mechanism comprises:
a polishing pad which polishes the opaque film;
a polishing table which supports the polishing pad; and
a top ring which holds a substrate having the laminated body provided thereon, and rotates the substrate while pressing it against the polishing pad.

18. The apparatus of claim 16,
wherein the detecting section comprises a spectroscope, and
the judgment section performs:
identifying a film thickness of the transparent film by carrying out fitting between a spectral profile measured at a time point that the intensity comparison value of the signals has substantially reached a predetermined threshold and a prepared first library of theoretical spectral profiles of the transparent film and the opaque film;
identifying the film thickness of the opaque film based on the identified film thickness of the transparent film; and
judging whether the film thickness of the opaque film has reached the desired film thickness based on the identified film thickness of the opaque film.

19. The apparatus of claim 16,
wherein the judgment section performs:
identifying a film thickness of the transparent film by carrying out fitting between signal intensity at a time point that intensity comparison value of the signals has substantially reached a predetermined threshold value and a prepared second library of theoretical profiles of the transparent film;
identifying the film thickness of the opaque film based on the identified film thickness of the transparent film; and
judging whether the film thickness of the opaque film has reached the desired film thickness based on the identified film thickness of the opaque film.

20. The apparatus of claim 16,
wherein the polishing mechanism comprises:
a chamber in which a gas introduction port and a gas discharge port are provided, a gas being introduced from an external gas source through the gas introduction port, a gas after a treatment being discharged through the gas discharge port;
a stage which is arranged in the chamber and holds a substrate having the laminated body provided thereon; and
a plasma generation unit which applies high-frequency power to the stage and converts the gas introduced in the chamber into plasma.
